(19) United States
(12) Patent Application Publication
(10) Pub. No.: US 2018/0192524 A1
(43) Pub. Date: Jul. 5, 2018

(54) FORMING METHOD OF CONTACT HOLE PATTERN

(71) Applicant: JSR CORPORATION, Tokyo (JP)

(72) Inventor: Hitoshi OSAKI, Tokyo (JP)

(73) Assignee: JSR CORPORATION, Tokyo (JP)

(21) Appl. No.: 15/396,067

(22) Filed: Dec. 30, 2016

(51) Int. Cl. H05K 3/42; B05D 1/00; B05D 3/02; G03F 7/00; B05D 3/10

(52) U.S. Cl. CPC H05K 3/425; B05D 1/005; B05D 3/107; G03F 7/0002; B05D 3/0254

(57) ABSTRACT

A contact hole pattern-forming method includes forming a hole pattern on a front face side of a substrate, directly or via other layer. A first composition including a first polymer is applied circularly in a planar view so as to coat lateral faces of holes of the hole pattern. A resin layer is provided on the front face side of the substrate and inside the lateral faces of the holes from a second composition including a second polymer. The resin layer is heated. A part of the resin layer heated is removed. The substrate is etched using a resist pattern formed. The first polymer includes a group being bound to at least one end of a main chain of the first polymer, and being capable of interacting with a third polymer constituting the hole pattern. The second polymer is a homopolymer or a random copolymer.

### BACKGROUND OF THE INVENTION

### Field of Invention

The present invention relates to a contact hole pattern-forming method.

### Description of the Related Art

In these days, microfabrication of various types of electronic device structures such as semiconductor devices and liquid crystal devices has been accompanied by demands for miniaturization of patterns in lithography processes. To meet such demands, methods have been proposed in which a finer pattern is formed by using a phase separation structure formed through directed self-assembly of a block copolymer produced by copolymerization of a first monomer having one property, and a second monomer having a property distinct from that of the first monomer (see, Japanese Unexamined Patent Application, Publication No. 2008-149447, Japanese Unexamined Patent Application (Translation of PCT Application), Publication No. 2002-519728, and Japanese Unexamined Patent Application, Publication No. 2003-218383).

By way of use of any one of such methods, a method has been contemplated in which after a composition containing a block copolymer is applied on a film having a formed hole pattern, a concentrically cylindrical phase separation structure is formed, followed by removing a central phase of the phase separation structure, whereby a contact hole pattern is formed having a hole diameter smaller than that of the hole pattern (see US Patent Application, Publication No. 2010/0297847).

### PRIOR ART DOCUMENTS

### Patent Documents

### Patent Documents

Patent Document 1: Japanese Unexamined Patent Application, Publication No. 2008-149447

Patent Document 2: Japanese Unexamined Patent Application (Translation of PCT Application), Publication No. 2002-519728

Patent Document 3: Japanese Unexamined Patent Application, Publication No. 2003-218383

Patent Document 4: US Patent Application, Publication No. 2010/0297847

### SUMMARY OF THE INVENTION

### Problems to be Solved by the Invention

However, a block copolymer is used in such conventional contact hole pattern-forming methods, and complicated steps are required for production of the same due to necessities for the block copolymer, such as high purity, etc. Therefore, the conventional contact hole pattern-forming methods are complicated, and consequently have a disadvantage of leading to also an increase in cost.

The present invention was made in view of the foregoing circumstances, and an object of the invention is to provide a contact hole pattern-forming method that enables a contact hole pattern having a sufficiently small hole diameter and a small CDU to be conveniently formed.

### Means for Solving the Problems

According to an aspect of the invention made for solving the aforementioned problems, a contact hole pattern-forming method comprises: forming a hole pattern on a front face side of a substrate, directly or via other layer; applying a first composition containing a first polymer and a solvent circularly in a planar view so as to coat lateral faces of holes of the hole pattern; providing from a second composition containing a second polymer and a solvent, a resin layer on the front face side of the substrate and inside the lateral faces of the holes coated with the first composition; heating the resin layer; removing a part of the resin layer heated; and etching the substrate using directly or indirectly a resist pattern formed from the hole pattern and the coating film overlaid on the lateral faces of the hole pattern and remaining after the removing, wherein the first polymer has a group being bound to at least one end of a main chain of the first polymer, and being capable of interacting with a third polymer constituting the hole pattern, and the second polymer is a homopolymer or a random copolymer.

The term “contact hole pattern” as referred to means a pattern of through-holes provided for connecting elements formed on a substrate, with each through-hole provided vertically with respect to the face of the substrate. The term “interacting” as referred to means, for example, forming a chemical bond between polymer molecules. The term “chemical bond” as referred to indicates a concept involving a covalent bond, an ionic bond and a coordinate bond, as well as an electrostatic attractive force and a hydrogen bond between/among molecules.

The term “homopolymer” as referred to means a polymer of one type of a monomer. The term “random copolymer” as referred to means a copolymer of two or more types of monomers that differ from one another, with a sequence of structural units derived from respective monomers being irregular.

### Effects of the Invention

The contact hole pattern-forming method of the aspect of the present invention enables a contact hole pattern having a sufficiently small hole diameter and a small CDU to be conveniently formed. Therefore, these can be suitably used for lithography processes in manufacture of various types of electronic devices such as semiconductor devices and liquid crystal devices for which further microfabrication is demanded.

### BRIEF DESCRIPTION OF THE DRAWINGS

FIG. 1 shows SEM images of patterns after each step of: (a) forming a hole pattern; (b) applying; and (c) removing, in the contact hole pattern-forming method according to an embodiment of the present invention.

### DESCRIPTION OF THE EMBODIMENTS

### Contact Hole Pattern-Forming Method

The contact hole pattern-forming method comprises:

the step of forming a hole pattern on a front face side of a substrate, directly or via other layer (hereinafter, may be also referred to as “hole pattern-forming step”);

the step of applying a first composition (hereinafter, may be also referred to as “composition (I)”) containing a first polymer (hereinafter, may be also referred to as “(A) polymer” or “polymer (A)”) and a solvent (hereinafter, may be also referred to as “(D) solvent” of “solvent (D)”) so as to coat lateral faces of holes of the hole pattern circularly in a planar view (hereinafter, may be also referred to as “applying step”);

the step of providing from a second composition (hereinafter, may be also referred to as “composition (II)”) containing a second polymer (hereinafter, may be also referred to as “(B) polymer” or “polymer (B)”) and (D) a solvent, a resin layer (hereinafter, may be also referred to as “(A) resin layer” or “resin layer (A)”) on the front face side of the substrate and inside the lateral faces of the holes coated with the composition (I) (hereinafter, may be also referred to as “resin layer-providing step”);

the step of heating the resin layer (A) (hereinafter, may be also referred to as “heating step”); and

the step of removing a part of the resin layer (A) heated (hereinafter, may be also referred to as “removing step”); and the step of etching the substrate using directly or indirectly a resist pattern formed from the hole pattern and the coating film overlaid on the lateral faces of the hole pattern and remaining after the removing (hereinafter, may be also referred to as “etching step”).

In the contact hole pattern-forming method, the polymer (A) has a group (hereinafter, may be also referred to as “group (I)”) being bound to at least one end of a main chain of the polymer (A), and being capable of interacting with a third polymer constituting the hole pattern (hereinafter, may be also referred to as “(C) polymer” or “polymer (C)”), and the polymer (B) is a homopolymer or a random copolymer. Hereinafter, each step will be described with reference to the drawings.

### Hole Pattern-Forming Step

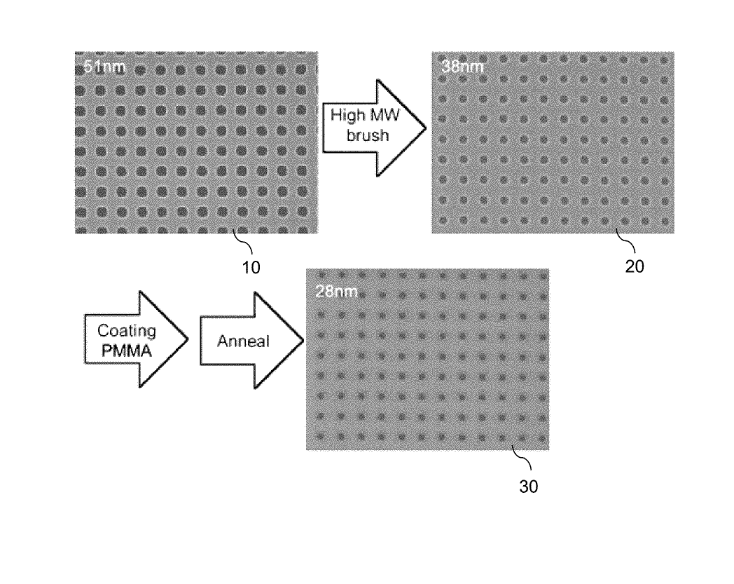

In this step, a hole pattern is formed on the front face side of a substrate directly or via other layer. FIG. 1(a) shows an SEM image, viewed from above, of a hole pattern formed in this step. This hole pattern may be directly formed on the front face of a substrate, or after forming an underlayer film, a spin-on glass (SOG) film and/or a radiation-sensitive resin film on the substrate, the hole pattern may be directly formed on a face side, not facing the substrate, of these films on the substrate. In light of possible formation of the contact hole pattern in a convenient manner on the substrate by etching using as a mask the hole pattern after the removing step described later, it is preferred that the hole pattern is directly formed on the front face of the substrate. Alternatively, it is preferred that after forming an underlayer film directly on the front face of the substrate, the hole pattern is formed on the underlayer film.

As a procedure of forming a hole pattern on an underlayer film, for example, the following procedure may be exemplified. An underlayer film is formed on the front face of a substrate by using a composition for underlayer film formation. As needed, an SOG film is formed on a face side, not facing the substrate, of the underlayer film by using an SOG composition. Next, a radiation-sensitive resin film is provided on a face side, not facing the substrate, of the underlayer film or the SOG film by using a radiation-sensitive resin composition. Then, this radiation-sensitive resin film is exposed and developed, whereby a hole resin film pattern is formed. In a case where the SOG film was formed by using this resin film pattern as a mask, the SOG film and the underlayer film are sequentially etched, whereas in a case where the SOG film was not formed, the underlayer film is etched.

As a substrate, a conventionally known substrate such as, for example, a silicon (Bare-Si) wafer, a wafer coated with aluminum may be exemplified.

As the composition for underlayer film formation, a conventionally known organic underlayer film-forming material or the like may be used, and for example, a composition for underlayer film formation containing a crosslinking agent and the like may be exemplified. Exemplary compositions for underlayer film formation include compositions for underlayer film formation containing a novolak resin as a polymer, and 1,3,4,6-tetrakis(methoxymethyl)glycoluril as crosslinking agent, and the like.

The forming procedure of the underlayer film is not particularly limited, and, for example, a process in which after applying a composition for underlayer film formation on the front face of the substrate by a known procedure such as spin coating, followed by prebaking (PB), the resultant coating film is hardened by carrying out irradiation with a radioactive ray and/or heating, and the like may be exemplified. Examples of the radioactive ray for use in irradiation include: electromagnetic waves such as a visible light ray, an ultraviolet ray, a far ultraviolet ray, an X-ray and a γ-ray; particle rays such as electron beam, a molecular beam and an ion beam; and the like. The lower limit of the temperature of the heating is preferably 90° C., more preferably 120° C., and still more preferably 150° C. The upper limit of the temperature of is preferably 550° C. and more preferably 450° C., and a temperature of no higher than 300° C. is even more preferred. The lower limit of the heating time period is preferably 5 sec, more preferably 10 sec, and still more preferably 20 sec. The upper limit of the time period is preferably 1,200 sec, more preferably 600 sec, and still more preferably 300 sec. The lower limit of the average thickness of the underlayer film is preferably 10 nm, more preferably 30 nm, and still more preferably 50 nm. The upper limit of the average thickness is preferably 1,000 nm, more preferably 500 nm, and still more preferably 200 nm.

As the SOG composition, a conventionally known SOG composition or the like may be used, and for example, a composition containing organic polysiloxane, and the like may be exemplified.

The forming procedure of the SOG film is not particularly limited, and, for example, a process in which after applying an SOG composition on the front face of the substrate or on the face of the underlayer film not facing the substrate by a known procedure such as spin coating, followed by PB, the resultant coating film is hardened by carrying out irradiation with a radioactive ray and/or heating, and the like may be exemplified. Examples of the radioactive ray for use in irradiation include radioactive rays similar to those exemplified as radioactive rays employed upon irradiating the coating film in forming the underlayer film, and the like. The lower limit of the temperature of the heating is preferably 100° C., more preferably 150 ° C., and still more preferably 180° C. The upper limit of the temperature is preferably 450° C., more preferably 400° C., and still more preferably 350 ° C. The lower limit of the heating time period is preferably 5 sec, more preferably 10 sec, and still more preferably 20 sec. The upper limit of the time period is preferably 1,200 sec, more preferably 600 sec, and still more preferably 300 sec. The lower limit of the Average thickness of the SOG film is preferably 10 nm, more preferably 15 nm, and still more preferably 20 nm. The upper limit of the average thickness is preferably 1,000 nm, more preferably 500 nm, and still more preferably 100 nm.

As the radiation-sensitive resin composition, for example, a conventional radiation-sensitive resin composition such as a composition containing a polymer having an acid-labile group, a radiation-sensitive acid generator and a solvent, and the like may be exemplified.

In the procedure of resin film pattern formation, the radiation-sensitive resin composition is first applied on: the front face of the substrate; a face of the underlayer film not facing the substrate; or a face of the SOG film not facing the substrate, and thereafter prebaking (PB) is carried out, whereby a radiation-sensitive resin film is formed. Next, an exposure is carried out through a mask pattern for forming the hole pattern having a desired shape. Examples of the radioactive ray which may be used for the exposure include electromagnetic waves such as an ultraviolet ray, a far ultraviolet ray, an extreme ultraviolet ray (EUV), and an X-ray; charged particle rays such as an electron beam and an a-ray, and the like. Of these, the far ultraviolet ray is preferred, an ArF excimer laser beam and a KrF excimer laser are more preferred, and an ArF excimer laser beam is still more preferred. As the exposure process, a process in which liquid immersion lithography is carried out may be exemplified. After the exposure, it is preferred that post exposure baking (PEB) is carried out. Then, a development is carried out by using a developer solution such as an alkaline developer solution or an organic solvent.

The lower limit of the average thickness of the radiation-sensitive resin film is preferably 10 nm, more preferably 30 nm, and still more preferably 50 nm. The upper limit of the average thickness is preferably 1,000 nm, more preferably 500 nm, and still more preferably 200 nm.

The shape of the hole pattern may be appropriately selected depending on the shape of the formed contact hole pattern that the substrate will finally have, and is exemplified by: circular such as true circular and elliptic; polygonal e.g., quadrilateral such as regular tetragonal, rectangular and trapezoidal, triangular such as regular triangular and isosceles triangular; and the like. Of these, in light of the possibility of more conveniently forming the contact hole pattern, the shape of the formed pattern is preferably circular, and more preferably true circular.

The lower limit of the average diameter of the hole pattern to be formed is preferably 10 nm, more preferably 20 nm, still more preferably 25 nm, and particularly preferably 30 nm. The upper limit of the average diameter is preferably 200 nm, more preferably 100 nm, still more preferably 70 nm, and particularly preferably 50 nm.

Thus obtained hole pattern is preferably subjected to a treatment of, for example, irradiating with an ultraviolet ray of 254 nm, etc., followed by heating at 100° C. or higher and 200° C. or lower for a time period of no less than 1 min and no greater than 30 min so as to promote hardening.

In addition, the face inside the holes of the hole pattern may be subjected to a hydrophobilization treatment or a hydrophilization treatment. A specific treatment procedure may be exemplified by e.g., a hydrogenation treatment including an exposure to hydrogen plasma for a certain period of time. By increasing the hydrophobicity or hydrophilicity of the face inside the holes of the hole pattern, a more increase in the thickness of the formed coating film of the composition (I) described later may be enabled.

### Applying Step

In this step, the composition (I) is applied so as to coat lateral faces of holes of the hole pattern circularly in a planar view. Accordingly, a coating film of the composition (I) is formed on at least the lateral faces inside the holes of the hole pattern. FIG. 1(b) shows an SEM image, viewed from above, of the hole pattern provided with the coating film. The composition (I) is directly applied on the lateral faces of the holes of the hole pattern. The composition (I) may be applied on, in addition to the lateral faces of the holes of the hole pattern, bottom faces of the hole pattern, i.e., the front face of the substrate, and the like.

In this step, the composition (I) is applied inside the lateral faces of the holes of the hole pattern, and then PB is carried out, whereby the coating film is provided. The applying procedure is exemplified by spin coating and the like.

It is preferred that the coating film formed is heated. The heating means may be exemplified by an oven, a hot plate and the like. The lower limit of the temperature of the heating is preferably 80° C., more preferably 100° C., and still more preferably 150° C. The upper limit of the temperature is preferably 400° C., more preferably 350° C., and still more preferably 300° C. The lower limit of the heating time period is preferably 10 sec, more preferably 20 sec, and still more preferably 20 sec. The upper limit of the time period is preferably 120 min, more preferably 10 min, and still more preferably 5 min.

In addition, the coating film thus formed is preferably rinsed with a rinse agent. The rinsing eliminates the polymer (A), etc., that failed to interact with the polymer (C) constituting the hole pattern. As the rinse agent, an organic solvent is typically used, and for example, a polyhydric alcohol partially etherated carboxylate solvent such as propylene glycol monomethyl ether acetate may be used.

The lower limit of the average thickness of the coating film formed is preferably 1 nm, more preferably 5 nm, and still more preferably 10 nm. The upper limit of the average thickness is preferably 50 nm, more preferably 40 nm, and still more preferably 30 nm.

### Composition (I)

The composition (I) contains the polymer (A) and the solvent (D). The composition (I) may contain other component except for the polymer (A) and the solvent (D), within a range not leading to impairment of the effects of the present invention.

(A) Polymer

The polymer (A) has a group (I) being bound to at least one end of a main chain of the polymer (A), and being capable of interacting with the polymer (C) constituting the hole pattern. The polymer (A) may be either a homopolymer or a copolymer as long at has the group (I) bound to at least one end of a main chain of the polymer (A). Moreover, in the case where the polymer (A) is a copolymer, it may be a random copolymer, a block copolymer, or a polymer having a gradient structure. It is preferred that the polymer (A) has the group (I) at one end of the main chain of the polymer (A).

Group (I)

The group (I) interacts with the polymer (C) constituting the hole pattern.

In a case where the hole pattern is formed from the underlayer film, or in a case where the hole pattern is formed by using the radiation-sensitive resin composition, and carrying out an exposure and development with an organic solvent, the polymer (C) is exemplified by a polymer having at least one of —COOH and —OH, and the like, and examples of the polymer (C) include novolak resins having a phenolic hydroxyl group, and the like.

In a case where the polymer (C) has —OH and/or —COOH, the group (I) is exemplified by: groups having —OH, —SH, —COOH, a cyano group, a vinyl group, a cyclic ether group, an alkoxy group or the like; and the like.

Examples of the cyclic ether group include an oxiranyl group, an oxetanyl group, an oxacyclopentyl group, an oxacyclohexyl group, and the like.

Examples of the alkoxy group include a methoxy group, an ethoxy group, a propoxy group, a butoxy group, a pentyloxy group, a 2-ethylhexyloxy group, and the like.

An exemplary group (I) includes a group represented by: —X—(Y)n (wherein, n is an integer of 1 to 3), and the like. X represents a hydrocarbon group having 1 to 20 carbon atoms and having a valency of (n+1). Y represents —OH, —SH, —COON, a cyano group, a vinyl group, a cyclic ether group or an alkoxy group.

Examples of the hydrocarbon group having 1 to 20 carbon atoms and having a valency of (n+1), represented by X include:

chain hydrocarbons having 1 to 20 carbon atoms, e.g., alkanes such as methane, ethane and propane;

alicyclic hydrocarbon having 3 to 20 carbon atoms, e.g., cycloalkanes such as cyclopentane, cyclohexane and methylcyclohexane;

groups obtained by removing (n+1) hydrogen atoms from aromatic hydrocarbons having 6 to 20 carbon atoms, e.g., arenes such as benzene, naphthalene, toluene and ethylbenzene; and the like.

Examples of the group (I) include a group represented by the following formula, a 2-hydroxy-3-methoxypropyl group, a 2-hydroxy-3-(2-ethylhexyloxy)propyl group, and the like.

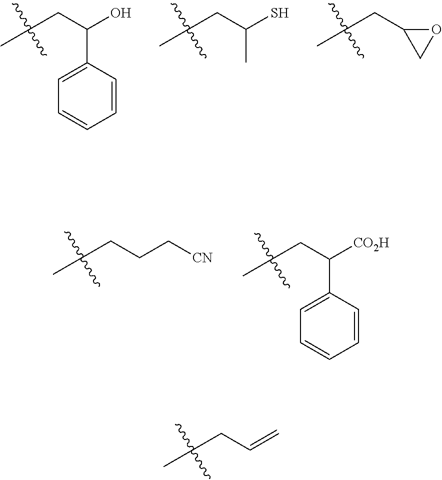

The group (I) is preferably a group having —OH, a group having —SH or a group having —COOH, more preferably a group having —OH, and still more preferably a 2-hydroxy-3-methoxypropyl group or a 2-hydroxy-3-(2-ethylhexyloxy)propyl group.

The monomer that gives the main chain of the polymer (A) is exemplified by substituted or unsubstituted styrene, a (meth)acrylic acid ester, substituted or unsubstituted ethylene (except for those corresponding to the substituted or unsubstituted styrene and the (meth)acrylic acid ester).

Examples of the substituted styrene include: a-methylstyrene; o-, m-, p-methylstyrene; p-t-butylstyrene; 2,4,6-trimethylstyrene; p-methoxystyrene; p-t-butoxystyrene; o-, m-, p-vinylstyrene; o-, m-, p-hydroxystyrene; m-, p-chloromethylstyrene; p-chlorostyrene; p-bromostyrene; p-iodostyrene; p-nitrostyrene; p-cyano styrene; and the like.

Examples of the (meth)acrylic acid ester include:

(meth)acrylic acid alkyl esters such as methyl (meth)acrylate, ethyl (meth)acrylate, t-butyl (meth)acrylate and 2-ethylhexyl (meth)acrylate;

(meth)acrylic acid cycloalkyl esters such as cyclopentyl (meth)acrylate, cyclohexyl (meth)acryl ate, 1-methylcyclopentyl (meth)acrylate, 2-ethyladamantyl (meth)acrylate and 2-(adamantan-1-yl)propyl (meth)acrylate;

(meth)acrylic acid aryl esters such as phenyl (meth)acrylate and naphthyl (meth)acrylate;

(meth)acrylic acid hydroxyhydrocarbon esters such as 2-hydroxyethyl (meth)acrylate and 3-hydroxyadamantyl (meth)acrylate;

(meth)acrylic acid substituted alkyl esters such as 3-glycidylpropyl (meth)acrylate and 3-trimethylsilylpropyl (meth)acrylate;

(meth)acrylic acid hydroxyhydrocarbon esters including, e.g., (meth)acrylic acid hydroxyalkyl esters such as hydroxyethyl (meth)acrylate, hydroxypropyl (meth)acrylate and hydroxybutyl (meth)acrylate; (meth)acrylic acid hydroxycycloalkyl esters such as hydroxycyclohexylmethyl (meth)acrylate; (meth)acrylic acid hydroxyaromatic esters such as hydroxyphenyl (meth)acrylate and hydroxybenzyl (meth)acrylate;

(meth)acrylic acid sulfanyl hydrocarbon esters including, e.g., (meth)acrylic acid sulfanylalkyl esters such as sulfanylethyl (meth)acrylate, sulfanylpropyl (meth)acrylate and sulfanylbutyl (meth)acrylate; (meth)acrylic acid sulfanylcycloalkyl esters such as sulfanylcyclohexylmethyl (meth)acrylate; (meth)acrylic acid sulfanyl aromatic esters such as sulfanylphenyl (meth)acrylate and sulfanylbenzyl (meth)acrylate; and the like.

Examples of the substituted ethylene include:

alkenes such as propene, butene and pentene;

vinylcycloalkanes such as vinylcyclopentane and vinylcyclohexane; cycloalkenes such as cyclopentene and cyclohexene;

4-hydroxy- 1 -butene, vinyl glycidyl ether, vinyl trimethylsilyl ether; and the like.

The monomer that gives the main chain of the polymer (A) is preferably substituted or unsubstituted styrene, and more preferably unsubstituted styrene.

The lower limit of the content of the polymer (A) in the composition (I) is, with respect to the total solid content in the composition (I) (total of the component(s) other than the solvent (D)), preferably 80% by mass, more preferably 90% by mass, and still more preferably 95% by mass. The composition (I) may contain one, or two or more types of the polymer (A), and preferably contains one type of the polymer (A).

Synthesis Process of Polymer (A)

The polymer (A) may be synthesized by a polymerization process that enables a terminal group to be introduced, such as, for example, living cationic polymerization, living anionic polymerization, living radical polymerization, coordination polymerization (Ziegler-Natta catalyst, metallocene catalyst), or the like. Alternatively, the polymer (A) may be also synthesized by radical polymerization in which a radical polymerization initiator is used having a structure that serves as a terminal group. Of these, in light of easier introduction of a terminal group to be enabled, living anionic polymerization is preferred.

Examples of the anionic polymerization initiator which may be used in the living anionic polymerization include:

alkyl lithium, alkylmagnesium halide, naphthalene sodium alkylated lanthanoid compounds;

potassium alkoxides such as t-butoxy potassium and 18-crown-6-ether potassium;

alkyl zinc such as dimethyl zinc and diethyl zinc;

alkyl aluminum such as trimethyl aluminum;

aromatic metal compounds such as benzyl potassium, cumyl potassium and cumyl cesium. Of these, alkyl lithium is preferred.

Examples of the solvent used in the living anionic polymerization include:

alkanes such as n-pentane, n-hexane, n-heptane, n-octane, n-nonane and n-decane;

cycloalkanes such as cyclohexane, cycloheptane, cyclooctane, decalin and norbornane;

aromatic hydrocarbons such as benzene, toluene, xylene, ethylbenzene and cumene;

saturated carboxylic acid esters such as ethyl acetate, n-butyl acetate, i-butyl acetate and methyl propionate;

ketones such as acetone, 2-butanone, 4-methyl-2-pentanone, 2-heptanone and cyclohexanone;

ethers such as tetrahydrofuran, dimethoxyethanes and diethoxyethanes; and the like. One, or two or more types of these solvents may be used.

The reaction temperature in the living anionic polymerization may be appropriately selected in accordance with the type of the anionic polymerization initiator, the lower limit of the reaction temperature is preferably −150° C., and more preferably −80° C. The upper limit of the reaction temperature is preferably 50° C., and more preferably 40° C. The lower limit of the reaction time period is preferably 5 min, and more preferably 20 min. The upper limit of the reaction time period is preferably 24 hrs, and more preferably 12 hrs.

The polymer (A) formed by the polymerization is preferably recovered by a reprecipitation technique. More specifically, after completion of the reaction, the reaction liquid is charged into a reprecipitation solvent to recover the intended polymer in a powder form. As the reprecipitation solvent, alcohol, ultra pure water, alkane and the like may be used alone or as a mixture of two or more types thereof. Not only the reprecipitation technique, a liquid separation operation, as well as a column operation, a ultrafiltration operation and the like may be employed to recover the polymer through removing low-molecular weight components such as monomers and oligomers.

The lower limit of the polystyrene equivalent weight average molecular weight (Mw) as determined by gel permeation chromatography (GPC) of the polymer (A) is preferably 3,000, more preferably 5,000, even more preferably 7,000, and particularly preferably 9,000. The upper limit of the Mw is preferably 100,000, more preferably 50,000, even more preferably 30,000, and particularly preferably 15,000.

The lower limit of the polystyrene equivalent number average molecular weight (Mn) of the polymer (A) is preferably 3,000, more preferably 5,000, still more preferably 7,000, and particularly preferably 9,000. The upper limit of the Mn is preferably 100,000, more preferably 50,000, still more preferably 30,000, and particularly preferably 15,000.

The upper limit of a dispersity index (Mw/Mn) of the polymer (A) is preferably 5, more preferably 3, still more preferably 2, particularly preferably 1.5, more particularly preferably 1.2, and most preferably 1.1. The lower limit of the dispersity index is typically 1.

The Mw and Mn of the polymer herein are values determined by GPC through using GPC columns (for example: “G2000 HXL” ×2; “G3000 HXL” ×1; and “G4000 HXL” ×1, available from Tosoh Corporation), under analytical conditions involving: the flow rate of 1.0 mL/min; the elution solvent of tetrahydrofuran; sample concentration of 1.0% by mass; the amount of injected sample of 100 μL; and the column temperature of 40° C., with a differential refractometer as a detector, based on mono-dispersed polystyrene as a standard.

(D) Solvent

The solvent (D) contained in the composition (I) is not particularly limited as long as it can dissolve or disperse at least the polymer (A) and other component(s).

The solvent (D) is exemplified by an alcohol solvent, an ether solvent, a ketone solvent, an amide solvent, an ester solvent, a hydrocarbon solvent, and the like.

Examples of the alcohol solvent include:

monohydric alcohol solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol and diacetone alcohol;

polyhydric alcohol solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol and tripropylene glycol;

polyhydric alcohol partially etherated solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether and dipropylene glycol monopropyl ether; and the like.

Examples of the ether solvent include:

dialkyl ether solvents such as diethyl ether, dipropyl ether and dibutyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

acetic acid ester solvents such as methyl acetate, ethyl acetate, n-propyl acetate, iso-propyl acetate, n-butyl acetate, iso-butyl acetate, sec-butyl acetate, n-pentyl acetate, i-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate and n-nonyl acetate;

polyhydric alcohol partially etherated carboxylate solvents such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monomethyl ether propionate, propylene glycol monoethyl ether acetate, propylene glycol monopropyl ether acetate, propylene glycol monobutyl ether acetate, dipropylene glycol monomethyl ether acetate and dipropylene glycol monoethyl ether acetate;

lactone solvents such as y-butyrolactone and valerolactone;

carbonate solvents such as dimethyl carbonate, diethyl carbonate, ethylene carbonate and propylene carbonate;

glycol diacetate, methoxytriglycol acetate, ethyl propionate, n-butyl propionate, iso-amyl propionate, diethyl oxalate, di-n-butyl oxalate, methyl acetoacetate, ethyl acetoacetate, methyl lactate, ethyl lactate, n-butyl lactate, n-amyl lactate, diethyl malonate, dimethyl phthalate, and diethyl phthalate; and the like.

Examples of the hydrocarbon solvent include:

aliphatic hydrocarbon solvents such as n-pentane, iso-pentane, n-hexane, iso-hexane, n-heptane, iso-heptane, 2,2,4-trimethylpentane, n-octane, iso-octane, cyclohexane and methylcyclohexane;

aromatic hydrocarbon solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene and n-amylnaphthalene; and the like.

Of these, the ester solvent and the ketone solvent are preferred; the ester solvent is more preferred; the polyhydric alcohol partially etherated carboxylate solvent is still more preferred; and propylene glycol monomethyl ether acetate is particularly preferred. The composition (I) may contain one, or two or types of the solvent (D).

Other Component

The other component in the composition (I) is exemplified by a surfactant, and the like. When the composition (I) contains the surfactant, the application property onto the hole pattern may be improved.

Preparation Method of Composition (I)

The composition (I) may be prepared by, for example, mixing the polymer (A), the solvent (D), and as needed the other component(s) at a predetermined ratio, and preferably filtering the resulting mixture through a membrane filter having a polar size of about 200 nm, etc. The lower limit of the solid content concentration of the composition (I) is preferably 0.1% by mass, more preferably 0.3% by mass, and still more preferably 0.5% by mass. The upper limit of the solid content concentration is preferably 30% by mass, more preferably 10% by mass, and still more preferably 5% by mass.

### Resin Layer-Providing Step

In this step, the resin layer (A) is provided from the composition (II) inside the lateral faces of the holes coated with the composition (I). More specifically, the resin layer (A) is provided inside the holes having the coating film of the composition (I) formed thereon. The resin layer (A) is typically provided such that filling therewith is permitted: on the front face of a substrate, etc., in other words: immediately above the front face of the substrate or immediately above a face, not facing the substrate, of the coating film of the composition (I) directly overlaid on the front face of the substrate; and on the surface of the coating film of the composition (I) on the lateral faces of the holes.

The resin layer (A) may be formed by applying the composition (II) onto the surface of the coating film of the composition (I) formed on lateral faces of the hole pattern, for example, by spin coating or the like, and then carrying out PB. The average height of the resin layer (A) is not particularly limited, and is preferably approximate to the average height of the hole pattern.

### Composition (II)

The composition (II) contains the polymer (B) and the solvent (D). The composition (II) may contain other component except for the polymer (B) and the solvent (D), within a range not leading to impairment of the effects of the present invention. Hereinafter, each component will be described.

(B) Polymer

The polymer (B) is a homopolymer or a random copolymer.

One type of monomer that gives the homopolymer, and two or more types of monomers that give the random copolymer are exemplified by monomers similar to those exemplified as the monomer that may give the polymer (A).

The random copolymer is preferably a random copolymer formed from two types of monomers. In this case, the lower limit of the molar ratio of the two types of monomers that give the random copolymer is preferably 10/90, more preferably 30/70, and still more preferably 40/60. The upper limit of the molar ratio is preferably 90/10, more preferably 70/30, and still more preferably 60/40.

The polymer (B) may have a terminal group on at least one end of a main chain of the same. Examples of the terminal group include groups having —OH, —COOH, —SH, etc., and the like.

The homopolymer as the polymer (B) is preferably a homopolymer of substituted or unsubstituted styrene, a homopolymer of a (meth)acrylic acid ester, and a homopolymer of substituted or unsubstituted ethylene, more preferably a homopolymer of a (meth)acrylic acid ester, still more preferably a homopolymer of methyl (meth)acrylate, and particularly preferably a homopolymer of methyl (meth)acrylate not having a terminal group, and a homopolymer of methyl (meth)acrylate having as a terminal group a group having —OH.

The random copolymer as the polymer (B) is preferably a random copolymer of substituted or unsubstituted styrene with a (meth)acrylic acid ester, a random copolymer of substituted or unsubstituted styrene with substituted or unsubstituted ethylene, and a random copolymer of a (meth)acrylic acid ester with substituted or unsubstituted ethylene.

The lower limit of the content of the polymer (B) in the composition (II) is, with respect to the total solid content in the composition (II) (total of the component(s) other than the solvent (D)), preferably 80% by mass, more preferably 90% by mass, and still more preferably 95% by mass. The composition (II) may contain one, or two or more types of the polymer (B), and preferably contains one type of the polymer (B).

Synthesis Process of Polymer (B)

In the case of being the homopolymer, the polymer (B) may be synthesized by a polymerization process known such as radical polymerization and anionic polymerize. Whereas, in the case of being a random copolymer, the polymer (B) may be synthesized by known radical polymerization.

The lower limit of the Mw of the polymer (B) is preferably 1,000, more preferably 2,000, still more preferably 3,000, and particularly preferably 3,500. The upper limit of the Mw is preferably 100,000, more preferably 50,000, still more preferably 30,000, and particularly preferably 10,000.

The lower limit of the Mn of the polymer (B) is preferably 1,000, more preferably 2,000, still more preferably 3,000, and particularly preferably 3,500. The upper limit of the Mn is preferably 100,000, more preferably 50,000, still more preferably 30,000, and particularly preferably 10,000.

The upper limit of the dispersity index of the polymer (B) is preferably 5, more preferably 3, still more preferably 2, particularly preferably 1.5, and more particularly preferably 1.2. The lower limit of the dispersity index is typically 1.

(D) Solvent

The solvent (D) contained in the composition (II) is not particularly limited as long as it is a solvent that is capable of dissolving or dispersing at least the polymer (B) and other component.

Of these, ester solvents and ketone solvents are preferred; ester solvents are more preferred; polyhydric alcohol partially etherated carboxylate solvents are still more preferred; and propylene glycol monomethyl ether acetate is particularly preferred. The composition (II) may contain one, or two or more types of the solvent (D).

Other Component

The other component in the composition (II) is exemplified by surfactants and the like. When the composition (II) contains a surfactant, coating characteristics inside the lateral faces of the holes can be improved.

Preparation Process of Composition (II)

The composition (II) may be prepared by, for example, mixing the polymer (B), the solvent (D) and as needed, other component at a certain ratio, and preferably filtrating through a membrane filter or the like having a pore size of about 200 nm. The lower limit of the solid content concentration of the composition (II) is preferably 0.1% by mass, more preferably 0.5% by mass, and still more preferably 1% by mass. The upper limit of the solid content concentration is preferably 30% by mass, more preferably 10% by mass, and still more preferably 5% by mass.

### Heating Step

In this step, the resin layer (A) is heated. The heating is considered to allow the polymer (B) constituting the resin layer (A) to interact with the polymer (A) and the like constituting the coating film of the composition (I), leading to occurrence of directed self-assembling, whereby a specific region (α) form would be formed as a result of alteration such as elongation of the polymer (A).

In the procedure of heating, for example, an oven, a hot plate or the like is used to execute the heating. The lower limit of the temperature of the heating is preferably 80° C., more preferably 100° C., and still more preferably 150° C. The upper limit of the temperature is preferably 400 ° C., more preferably 350° C., and still more preferably 300° C. The lower limit of the time period of the heating is preferably 10 sec, more preferably 20 sec, and still more preferably 30 sec. The upper limit of the time period is preferably 120 min, more preferably 100 min, and still more preferably 80 min.

### Removing Step

In this step, a part of the resin layer (A) after the applying step is removed. More specifically, by removing, in resin layer (A), the region other than the region (α) formed in the heating step, a contact hole pattern is formed having a hole diameter smaller than that of the hole pattern. FIG. 1 (c) shows an SEM image, viewed from above, of the contact hole pattern thus formed.

The removing procedure is exemplified by known techniques including: reactive ion etching (RIE) such as chemical dry etching carried out using CF₄, an O₂ gas or the like by utilizing the difference in etching rate of each region, etc., as well as chemical wet etching (wet development) carried out by using an etching liquid such as an organic solvent or hydrofluoric acid; physical etching such as sputtering etching and ion beam etching. Of these, the reactive ion etching is preferred, and the chemical dry etching and the chemical wet etching are more preferred.

Prior to the chemical dry etching, an irradiation with a radioactive ray may be also carried out as needed. As the radioactive ray, when the polymer (B) constituting the region to be removed by etching is provided by using methyl polymethacrylate, a radioactive ray of 172 nm or the like may be used. The irradiation with such a radioactive ray results in degradation of the structural unit derived from methyl methacrylate of the polymer (B), whereby the etching is facilitated.

Examples of the organic solvent for use in the chemical wet etching include:

alkanes such as n-pentane, n-hexane and n-heptane;

cycloalkanes such as cyclohexane, cycloheptane and cyclooctane;

saturated carboxylic acid esters such as ethyl acetate, n-butyl acetate, i-butyl acetate and methyl propionate;

ketones such as acetone, methyl ethyl ketone, methyl isobutyl ketone and methyl n-pentyl ketone;

alcohols such as methanol, ethanol, 1-propanol, 2-propanol and 4-methyl-2-pentanol; and the like. One, or two or more types of these solvents may be used.

### Etching Step

In this step, the substrate is etched by using directly or indirectly a resist pattern formed from the hole pattern and the coating film overlaid on the lateral faces of the hole pattern and remaining after the removing. The coating film overlaid on the lateral faces of the hole pattern and remaining after the removing is considered to include the coating film of the composition (I), the region (α) and the like. In this step, the contact hole pattern is formed on the substrate. In the case where the hole pattern is formed via other layer on the front face side of the substrate, this etching is executed on the other layer and the substrate, whereas in the case where any other layer is provided, the etching is executed on the substrate.

As the etching procedure, a procedure similar to that of in the removing step may be employed, and the etching gas and etching liquid may be appropriately selected in accordance with the material, etc., of the substrate. For example, in the case of the substrate being a silicon material, a gas mixture of chlorofluorocarbons gas and SF₄, etc., may be used. Alternatively, in the case of the substrate being a metal film, gas mixture of BCl₃ and Cl₂, etc., may be used.

After completion of the patterning onto the substrate, the sections (hole pattern, the coating film and the region (a)) used as a mask in the etching step are removed from the front face side of the substrate by a dissolving treatment or the like, whereby a substrate having the formed contact hole pattern can be finally obtained. The substrate obtained according to the contact hole pattern-forming method is suitably used for semiconductor elements and the like, and further the semiconductor elements are widely used for LED, solar cells, and the like.

### EXAMPLES

Hereinafter, the present invention is explained in detail by way of Examples, but the present invention is not in any way limited to these Examples. Measuring methods for various types of physical properties are shown below.

The Mw and the Mn of the polymer were determined by gel permeation chromatography (GPC) using GPC columns (Tosoh Corporation; “G2000 HXL” ×2, “G3000 HXL” ×1 and “G4000 HXL” ×1) under the following conditions:

eluent: tetrahydrofuran (Wako Pure Chemical Industries, Ltd.);

flow rate: 1.0 mL/min;

sample concentration: 1.0% by mass;

amount of sample injected: 100 μL;

column temperature: 40° C.;

detector: differential refractometer; and

standard substance: mono-dispersed polystyrene.

### ¹H-NMR Analysis

¹H-NMR analysis was carried out using a nuclear magnetic resonance apparatus (“JNM-Delta 400” available from JEOL, Ltd.), with deuterated chloroform for use as a solvent for measurement. The proportion of each structural unit in the polymer was calculated from an area ratio of a peak corresponding to each structural unit on the spectrum obtained by the ¹H-NMR.

### Synthesis of Polymer

Synthesis of Polymer (A)

### Synthesis Example 1

### Synthesis of Polymer (A-1)

After a 500-mL flask as a reaction vessel was dried under reduced pressure, 120 g of tetrahydrofuran (THF) which had been subjected to a distillation dehydrating treatment in a nitrogen atmosphere was charged, and cooled to −78° C. Thereafter, 3.10 mL (3.00 mmol) of a 1 N cyclohexane solution of sec-butyllithium (sec-BuLi) was charged into this THF, and then 16.6 mL (0.150 mol) of styrene which had been subjected to: adsorptive filtration by means of silica gel for removing the polymerization inhibitor; and a dehydration treatment by distillation was added dropwise over 30 min. The polymerization system color was ascertained to be orange. During the instillation, the internal temperature of the polymerization reaction mixture was carefully controlled so as not to be −60° C. or higher. After completion of the dropwise addition, aging was permitted for 30 min. Subsequently, a mixture of 1 mL of methanol and 0.63 mL (3.00 mmol) of 2-ethylhexyl glycidyl ether as a chain-end terminator was charged to conduct a terminating reaction of the polymerization end. The temperature of the polymerization reaction mixture was elevated to the room temperature, and the mixture was concentrated. Thereafter, substitution with methyl isobutyl ketone (MIBK) was carried out. Thereafter, 1,000 g of a 2% by mass aqueous oxalic acid solution was charged and the mixture was stirred. After leaving to stand, the aqueous underlayer was removed. This operation was repeated three times to remove the Li salt. Thereafter, 1,000 g of ultra pure water was charged and the mixture was stirred, followed by removing the aqueous underlayer. This operation was repeated three times to remove oxalic acid, and then the resulting solution was concentrated. Subsequently, the concentrate was added dropwise into 500 g of methanol to allow the polymer to be precipitated. The solid was collected on a Buechner funnel. Thus obtained solid was dried under reduced pressure at 60° C. to give 14.8 g of a polymer represented by the following formula (A-1) as a white solid. This polymer (A-1) had the Mw of 6,100, the Mn of 5,700, and the Mw/Mn of 1.07.

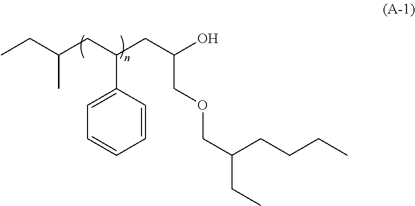

Synthesis of Polymer

### Synthesis Example 2

### Synthesis of Polymer (B-a)

After a 500-mL flask as a reaction vessel was dried under reduced pressure, 200 g of THF which had been subjected to a distillation dehydrating treatment in a nitrogen atmosphere was charged, and cooled to −78° C. Thereafter, 0.46 mL (0.41 mmol) of a 1 N cyclohexane solution of sec-BuLi was charged to this THF, and then 13.3 mL (0.115 mol) of styrene which had been subjected to: adsorptive filtration by means of silica gel for removing the polymerization inhibitor; and a dehydration treatment by distillation was added dropwise over 30 min. The polymerization system color was ascertained to be orange. During the instillation, the internal temperature of the polymerization reaction mixture was carefully controlled so as not to be −60° C. or higher. After completion of the dropwise addition, aging was permitted for 30 min. Thereafter, 0.18 mL (0.00124 mol) of 1,1-diphenylethylene, and 1.65 mL (0.0008 mol) of a 0.5 N THF solution of lithium chloride were added thereto, and the polymerization system color was ascertained to be dark red. Furthermore, 11.4 mL (0.108 mol) of methyl methacrylate which had been subjected to: adsorptive filtration by means of silica gel for removing the polymerization inhibitor; and a dehydration treatment by distillation was added dropwise to the polymerization reaction mixture over 30 min. The polymerization system color was ascertained to be light yellow, and thereafter the reaction was allowed to proceed for 120 min. Subsequently, 1 mL of methanol as a chain-end terminator was charged to conduct a terminating reaction of the polymerization end. The temperature of the polymerization reaction mixture was elevated to the room temperature, and the mixture was concentrated. Thereafter, substitution with MIBK was carried out. Thereafter, 1,000 g of a 2% by mass aqueous oxalic acid solution was charged and the mixture was stirred. After leaving to stand, the aqueous underlayer was removed. This operation was repeated three times to remove the Li salt. Thereafter, 1,000 g of ultra pure water was charged and the mixture was stirred, followed by removing the aqueous underlayer. This operation was repeated three times to remove oxalic acid, and then the solution was concentrated. Subsequently, the concentrate was added dropwise into 500 g of methanol to allow the polymer to be precipitated. The solid was collected on a Buechner funnel. Next, in order to remove the polystyrene homopolymer, 500 g of cyclohexanone/ heptane mixture (8/2 (mass ratio)) was poured and the polymer was washed, such that the polystyrene homopolymer contained was dissolved into the cyclohexane/heptane mixture. This operation was repeated four times, and again the solid was collected on a Buechner funnel. Thus obtained solid was dried under reduced pressure at 60° C. to give 22.5 g of a polymer represented by the following formula (B-a) having white color. This polymer (B-a) has the Mw of 56,200, the Mn of 54,000, and the Mw/Mn of 1.04. In addition, as a result of the ¹H-NMR analysis, the polymer (B-a) was revealed to be a diblock copolymer in which the proportion “m” of the structural unit derived from styrene, and the proportion “n” of the structural unit derived from methyl methacrylate were 50.2% by mass (49.2 mol %) and 49.8% by mass (50.8 mol %), respectively.

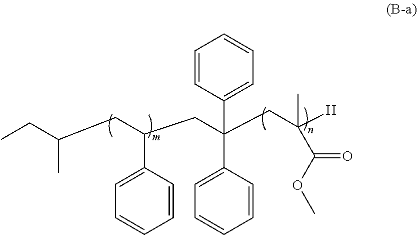

### Preparation of Composition

The polymer (A), the polymer (B) and the solvent (D) used in the preparation of the composition (I) and the composition (II) are shown below.

### (A) Polymer

A-1: polymer synthesized in Synthesis Example 1 (Mw=6,100, Mw/M=1.07)

A-2: ω-hydroxy-terminated polystyrene (available from Polymer Source Inc., Sample#: P18729-SOH; Mw=10,500, Mw/Mn=1.09)

A-3: ω-hydroxy-terminated polystyrene (available from Polymer Source Inc., Sample#: P18902-SOH; Mw=20,500, Mw/Mn=1.09)

### (B) Polymer

B-1: ω-hydroxy-terminated polymethyl methacrylate (manufactured by Polymer Source Inc., Sample#: P10423-MMAOH; Mw=4,600, Mw/Mn=1.15)

B-2: terminal unmodified polymethyl methacrylate (available from Polymer Source Inc., Sample#: P167-iMMA, Mw=4,800, Mw/Mn=1.3)

B-a: polymer synthesized in Synthesis Example 2 (Mw=56,200, Mw/Mn=1.04)

### (D) Solvent

D-1: propylene glycol monomethyl ether acetate

### Preparation of Composition (I)

### Preparation Example 1

A composition (S-1) was prepared by mixing 100 parts by mass of (A-1) as the polymer (A) and 9,900 parts by mass of (D-1) as the solvent (D), and then filtering the mixed solution thus obtained through a membrane filter having a pore size of 200 nm.

### Preparation Examples 2 and 3

Compositions (S-2) and (S-3) were prepared similarly to Preparation Example 1 except that each component of the type and content shown in Table 1 below was used.

TABLE 1

| | | Preparation | Preparation | Preparation |
|---|---|---|---|---|
| (part by mass) | | Example 1 | Example 2 | Example 3 |
| Composition (I) | | S-1 | S-2 | S-3 |
| (A) Polymer | A-1 | 100 | | |
| | A-2 | | 100 | |
| | A-3 | | | 100 |
| (D) Solvent | D-1 | 9,900 | 9,900 | 9,900 |

| | | | |
|---|---|---|---|
| Solid content | 1 | 1 | 1 |
| concentration (mass %) | | | |

### Preparation of Composition (II)

### Preparation Example 4

A composition (T-1) was prepared by mixing 100 parts by mass of (B-1) as the polymer (B) and 9,900 parts by mass of (D-1) as the solvent (D), and then filtering the mixed solution thus obtained through a membrane filter having a pore size of 200 nm.

### Preparation Examples 5 and 6

Compositions (T-2) and (T-3) were prepared similarly to Preparation Example 4 except that each component of the type and content shown in Table 2 below was used.

TABLE 2

| | | Preparation | Preparation | Preparation |
|---|---|---|---|---|
| (part by mass) | | Example 4 | Example 5 | Example 6 |
| Composition (II) | | T-1 | T-2 | T-a |
| (B) Polymer | B-1 | 100 | | |
| | B-2 | | 100 | |
| | B-a | | | 100 |
| (D) Solvent | D-1 | 9,900 | 9,900 | 16,566 |

| | | | |
|---|---|---|---|
| Solid content | 1 | 1 | 0.6 |
| concentration (mass %) | | | |

### Resist Pattern Formation

### Polymer for Hole Pattern (Synthesis of Polymer (C))

To a 500-mL three-neck flask equipped with a thermometer, a condenser and a magnetic stirrer were added 250.0 g of m-cresol, 125.0 g of 37% by mass formalin and 2 g of anhydrous oxalic acid in a nitrogen atmosphere, and then a reaction was allowed at 100° C. for 3 hrs, and at 180° C. for 1 hr. Unreacted monomer was removed under a reduced pressure to obtain a polymer (cresol novolak resin) having a repeating unit represented by the following formula (C-1). Thus obtained polymer (C-1) had the Mw of 11,000, and the Mw/Mn of 8.4.

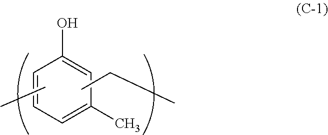

### Preparation of Composition for Hole Pattern Formation

In 90 parts by mass of propylene glycol monomethyl ether acetate were dissolved 10 parts by mass of the polymer (C-1) synthesized as above, 0.5 parts by mass of bis(4-t-butylphenyl)iodonium nonafluoro-n-butanesulfonate as an acid generating agent, and 3 parts by mass of 1,3,4,6-tetrakis(methoxymethyl)glycoluril as a crosslinking agent. A composition for hole pattern formation (P-1) was prepared by filtering thus obtained solution through a membrane filter having a pore size of 0.1 μm.

### Hole Pattern Formation

An underlayer film having an average thickness of 100 nm was formed on a bare-Si substrate by using a composition for hole pattern formation prepared as described above, and on this underlayer film, an SOG film having an average thickness of 30 nm was formed by using an SOG composition (“ISX302” available from JSR Corporation). On the substrate thus obtained, a positive type radiation-sensitive resin composition (“EUVJ2121” available from JSR Corporation) was applied to form a radiation-sensitive resin film having a thickness of 50 nm, which was then subjected to an EUV exposure. Development was carried out by using a 2.38% by mass aqueous tetrabutylammonium hydroxide solution to form a resin film pattern. Next, by using this resin film pattern as a mask, etching of the SOG film was carried out with a gas mixture of CF₄/O₂/Air. Then, the underlayer film was etched by using thus obtained SOG film pattern as a mask with an N₂/O₂ gas mixture to form a hole pattern.

### Example 1

A coating film was provided on the hole pattern formed as described above by using (S-2) as the composition (I), followed by baking at 200° C. for 20 min, and the coating film was rinsed with PGMEA. Subsequently, a resin layer was provided by using (T-1) as the composition (II), followed by baking at 220° C. for 20 min. Thereafter, a part of the resin layer was removed with an oxygen gas to form a resist pattern.

### Comparative Example 1

A coating film was provided on the hole pattern formed as described above by using (S-1) as the composition (I), followed by baking at 200° C. for 20 min, and the coating film was rinsed with PGMEA. Subsequently, a resin layer was provided by using (T-a) as the composition (II), followed by baking at 220° C. for 20 min to permit phase separation. Thereafter, the phase composed of PMMA blocks was removed with an oxygen gas to form a resist pattern.

### Examples 2 to 4

A coating film was provided on the hole pattern formed as described above by using compositions (I) shown in Table 3 below, followed by baking at 200° C. for 20 min, and the coating film was rinsed with PGMEA. Furthermore, the same composition (I) was used to provide a coating film, which was baked at 200° C. for 20 min, and rinsed with PGMEA. Subsequently, a resin layer was provided by using compositions (II) shown in Table 3 below, followed by baking at 220° C. for 20 min. Thereafter, a part of the resin layer was removed with an oxygen gas to form a resist pattern.

### Evaluation

CDU, minimum hole pattern size accompanied by occurrence of phase separation, and minimum hole size of the resist pattern after patterning were evaluated with respect to the resist pattern formed as described above, by using a scanning electron microscope (SEM). The results of the evaluations are shown in Table 3 below. It is to be noted that CDU (nm) is represented in terms of a standard deviation (3σ) of the hole size distribution, and a smaller CDU value indicates further suitability. A smaller minimum hole pattern size (nm) indicates applicability to a finer hole pattern with a smaller pitch. A smaller minimum hole size (nm) of the resist pattern indicates favorable formability of fine patterns.

TABLE 3

| | Com- | Com- | Minimum hole | Minimum hole | |
|---|---|---|---|---|---|
| | position | position | pattern size | size of resist | CDU |
| | (I) | (II) | (nm) | pattern (nm) | (nm) |
| Example 1 | S-2 | T-1 | 42.9 | 24.8 | 3.65 |
| Example 2 | S-2 | T-1 | 43.1 | 22.4 | 3.72 |
| Example 3 | S-2 | T-2 | 39.0 | 19.1 | 2.41 |
| Example 4 | S-3 | T-2 | 21.6 | 16.7 | 2.28 |
| Comparative | S-1 | T-a | 36.2 | 19.3 | 3.14 |
| Example 1 | | | | | |

From the results shown in Table 3, it was revealed that the contact hole pattern-forming methods of Examples enabled a resist pattern having a sufficiently small hole diameter and a small CDU to be conveniently formed by a novel process in which a block copolymer was not used. By using this resist pattern, it is expected that formation on a substrate, of a contact hole pattern having a sufficiently small hole diameter and a small CDU is enabled.

### INDUSTRIAL APPLICABILITY

The contact hole pattern-forming method of the aspect of the present invention enables a contact hole pattern having a sufficiently small hole diameter and a small CDU to be conveniently formed. Therefore, these can be suitably used for lithography processes in manufacture of various types of electronic devices such as semiconductor devices and liquid crystal devices for which further microfabrication is demanded.

1. A contact hole pattern-forming method comprising:
forming a hole pattern on a front face side of a substrate, directly or via other layer;
applying a first composition comprising a first polymer and a solvent circularly in a planar view so as to coat lateral faces of holes of the hole pattern;
applying a second composition comprising a second polymer and a solvent to form a resin layer on the front face side of the substrate and inside the lateral faces of the holes coated with the first composition;
heating the resin layer;
removing a part of the resin layer heated; and
etching the substrate using directly or indirectly a resist pattern formed from the hole pattern and the coating film overlaid on the lateral faces of the hole pattern and remaining after the removing, wherein
the first polymer comprises a group being bound to at least one end of a main chain of the first polymer, and being capable of interacting with a third polymer constituting the hole pattern, and
the second polymer is a homopolymer or a random copolymer and does not comprise a block copolymer.

2. The contact hole pattern-forming method according to claim 1,
wherein the first polymer is a styrene polymer, and the second polymer is a (meth)acrylic ester polymer.

3. The contact hole pattern-forming method according to claim 1, wherein the first polymer comprises a hydroxy group.

4. The contact hole pattern-forming method according to claim 2, wherein the first polymer comprises a hydroxy group.

5. The contact hole pattern-forming method according to claim 1, wherein the third polymer comprises —OH and/or —COOH.

6. The contact hole pattern-forming method according to claim 1, wherein the third polymer comprises a novolak resin having a phenolic hydroxyl group.

7. The contact hole pattern-forming method according to claim 1, wherein the main chain of the first polymer is made by polymerizing an unsubstituted styrene.

8. The contact hole pattern-forming method according to claim 1, wherein the second polymer has a terminal group on at least one end of a main chain of the second polymer, and the terminal group comprises —OH, —COOH, and/or —SH.

9. The contact hole pattern-forming method according to claim 1, wherein the second polymer is a homopolymer of a (meth)acrylic acid ester.

10. The contact hole pattern-forming method according to claim 1, wherein the second polymer is a homopolymer of methyl (meth)acrylate.

11. The contact hole pattern-forming method according to claim 1, wherein the second polymer is a homopolymer of methyl (meth)acrylate not having a terminal group, or a homopolymer of methyl (meth)acrylate having a terminal group which has —OH on at least one end of a main chain of the second polymer.

12. The contact hole pattern-forming method according to claim 1, wherein during the heating of the resin layer, the second polymer interacts with the first polymer to cause a directed self-assembling.

13. The contact hole pattern-forming method according to claim 2, wherein the third polymer comprises —OH and/or —COOH.

14. The contact hole pattern-forming method according to claim 2, wherein the third polymer comprises a novolak resin having a phenolic hydroxyl group.

15. The contact hole pattern-forming method according to claim 2, wherein the main chain of the first polymer is made by polymerizing an unsubstituted styrene.

16. The contact hole pattern-forming method according to claim 2, wherein the second polymer has a terminal group on at least one end of a main chain of the second polymer, and the terminal group comprises —OH, —COOH, and/or —SH.

17. The contact hole pattern-forming method according to claim 2, wherein the second polymer is a homopolymer of a (meth)acrylic acid ester.

18. The contact hole pattern-forming method according to claim 2, wherein the second polymer is a homopolymer of methyl (meth)acrylate.

19. The contact hole pattern-forming method according to claim 2, wherein the second polymer is a homopolymer of methyl (meth)acrylate not having a terminal group, or a homopolymer of methyl (meth)acrylate having a terminal group which has —OH on at least one end of a main chain of the second polymer.

20. The contact hole pattern-forming method according to claim 2, wherein during the heating of the resin layer, the second polymer interacts with the first polymer to cause a directed self-assembling.
